(19) United States
(12) Patent Application Publication
(10) Pub. No.: US 2017/0103939 A1
(43) Pub. Date: Apr. 13, 2017

(54) ULTRATHIN ROUTABLE QUAD FLAT NO-LEADS (QFN) PACKAGE

(71) Applicant: NXP B.V., Eindhoven (NL)

(72) Inventors: Jan Gulpen, Nijmegen (NL); Leonardus Antonius Elisabeth van Gemert, Nijmegen (NL); Tonny Kamphuis, Nijmegen (NL)

(21) Appl. No.: 14/880,076

(22) Filed: Oct. 9, 2015

(51) Int. Cl. H01L 23/495; H01L 21/48; H01L 21/56

(52) U.S. Cl. CPC H01L 23/49541; H01L 23/49503; H01L 23/4952; H01L 21/563; H01L 21/568; H01L 21/4825

(57) ABSTRACT

Consistent with an example embodiment, there is a method for preparing an integrated circuit (IC) device. The method comprises providing a lead frame, the lead frame having I/O terminals surrounding a die attach region, the lead frame defined onto a temporary carrier. A device die is attached onto the die-attach region. The device die is wire bonded to the I/O terminals, the I/O terminals located in a first position. In a molding compound the wire-bonded device die and lead frame are encapsulated. The temporary carrier is removed from the lead frame, underside surfaces of the device die and I/O terminals are exposed. Applying a non-conductive layer to the exposed underside surfaces of the device die and I/O terminals, thereby defines features in which conductive traces may be defined from the I/O terminals in the first position to customized I/O terminals located in a second position.

### FIELD

This disclosure relates to integrated circuit (IC) packaging. More particularly, this disclosure relates to a low-profile QFN package.

### BACKGROUND

The electronics industry continues to rely upon advances in semiconductor technologies to realize higher-function devices in more compact areas. Applications realizing higher-functioning devices require integrating a large number of electronic devices into a single silicon wafer. As the number of devices per given area of the silicon wafer increases, the manufacturing process becomes more difficult.

Many varieties of semiconductor devices have been manufactured having various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

In the manufacture of electronic devices on a wafer substrate, a particular challenge is to package these semiconductor devices in an appropriate package suitable for their given purpose.

### SUMMARY

The present disclosure addresses the challenge of making a QFN semiconductor having a lower vertical profile with routing capabilities to provide flexibility in the definition of I/O terminals. Carrier-based lead frames such as LLGA (leadless land grid array), TLA (thermal leadless array), EFLGA (electroforming type land grid array), and TLEM (transcription lead of electroforming method), etc, have been determined suitable for including additional processing such that the fixed locations of the input/output (I/O) terminals may be rerouted with conductive traces. These rerouted conductive traces customize the LLGA-like package to better fit a particular printed circuit board (PCB) sub-system to which the packaged device is mounted.

In an example embodiment, there is a method for preparing an integrated circuit (IC) device. The method comprises providing an lead frame, the lead frame having I/O terminals surrounding a die attach region, the lead frame defined onto a temporary carrier, attaching a device die onto the die attach region, wire bonding the device die to the I/O terminals, the I/O terminals located in a first position, encapsulating the device die and lead frame in a molding compound, removing the temporary carrier from lead frame, exposing underside surfaces of the device die and I/O terminals, and applying a non-conductive layer to the exposed underside surfaces of the device die and I/O terminals, thereby defining features in which conductive traces may be defined from the I/O terminals in the first position to customized I/O terminals located in a second position.

In an example embodiment, there is a semiconductor device, in a package. The semiconductor device comprises a lead frame having I/O terminals surrounding a die attach area, the I/O terminals having a first pitch between I/O terminals opposite one another. A device die is placed in the die attach area, the device die having active device circuits; the active device circuits are surrounded by I/O pads, the I/O pads having a second pitch between I/O pads opposite one another. A lead frame portion has I/O positions corresponding to the lead frame I/O terminals; the lead frame portion I/O positions have a third pitch between I/O positions opposite one another; the third pitch is substantially the same as the second pitch and the lead frame portion I/O positions are in electrical contact with the lead frame I/O terminals, thereby routing electrical signals from the device die I/O pads to external electrical contacts of the package. The I/O pads of the device die are in electrical contact with corresponding lead frame portion I/O positions. The lead frame, lead frame portions, and device die are enveloped in a molding compound, leaving surfaces of the external electrical contacts exposed.

The above summaries of the present invention are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIG. 1 is a flow diagram of an example assembly process in accordance with the present disclosure; and

FIGS. 2A-2G is a series of side views illustrated the assembly process of FIG. 1; and

FIGS. 3A-3C illustrates an example of package having pitch translation according to an embodiment of the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

As the complexity of portable systems increases, there is a commensurate need to reduce the size of the individual components that make up the system; the system often is laid out on a printed circuit substrate. One way to reduce the size of individual components is through techniques that reduce the size of packages containing these devices. A package, often used, is the QFN (quad flat no-leads) package to reduce the vertical profile of the devices attached to the system printed circuit substrate.

Carrier-based leadless platforms exist that make allow for very thin lead frame and therefore very low height packages. A carrier is used on which the lead frame is plated in one or multiple steps. The carrier is used for production handling and is removed after assembly once the molding compound has given the strips (which make up the lead frame) the required mechanical stability.

However, carrier-based lead frames do not allow for the routing of connections for the I/O terminals. Routing is necessary for pitch translation for flip-chip devices. Further, to minimize bond wire length within the package, routing is necessary.

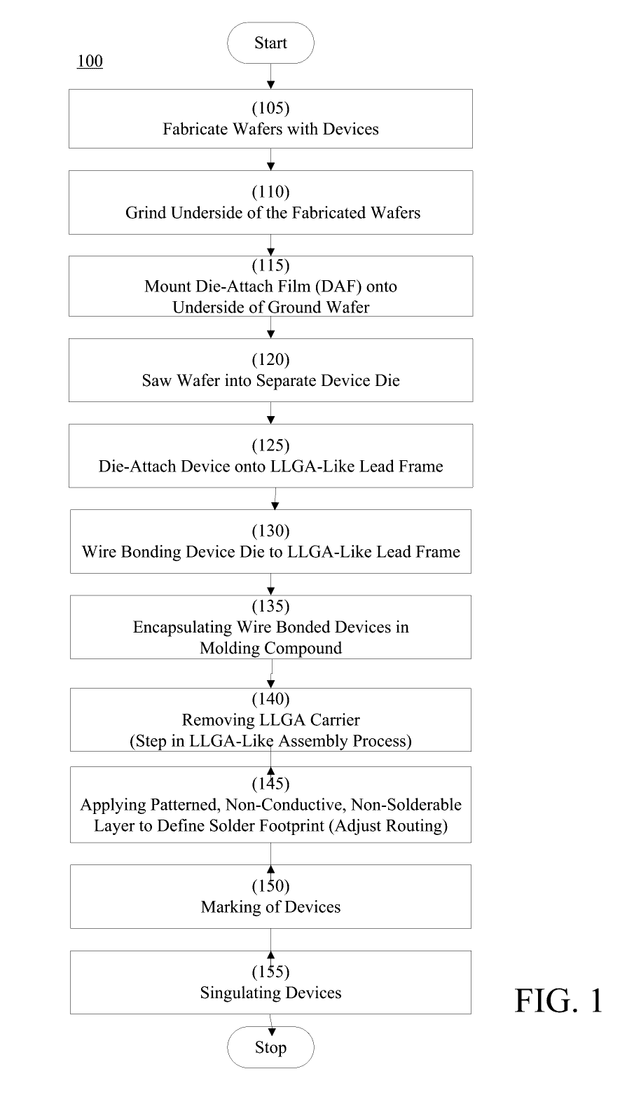

Refer to FIG. 1. An integrated circuit (IC) device is manufactured in a process according to the present disclosure. In step 105, on a wafer substrate, devices are manufactured. Depending upon device size and wafer substrate diameter, the number of devices possible may range from a few hundred to several thousand. After the devices have been completed, in step 110 the wafer substrate is mounted onto a grinding tape and undergoes a back grinding on the underside surface to thin out the wafer substrate. The underside surface is ground down to a prescribed thickness. In an example process, the prescribed thickness is a thickness for a device die that has completed the process. For example, a pre-grinding thickness, of a “twelve-inch” wafer (300 mm) is about 775 μm, for an “eight-inch” wafer (200 mm) about 725 μm. Note that this technique in the present disclosure may be applied to wafer substrates of any size and may be useful for “twelve-inch” (300 mm) substrates. After back grinding, the underside surface of the wafer may undergo an underside stress-reduction process that may include chemical mechanical polishing (CMP), dry polish, plasma polishing etc. The particular order of the polishing would be determined by specific manufacturing parameters. An example final thickness of the silicon part of the construction may range between about 30 μm to a about 240 μm.

In step 115, the ground wafer substrate is mounted onto a DAF (die attach film) on its underside surface. With a suitable technique, the wafer is sawed into separate device die at step 120. In step 125, known functional device die are mounted (i.e., die-attached) into an LLGA-like lead frame assembly having a plurality of IC device positions.

In step 130, the plurality of device die are wire bonded to the LLGA-like lead frame. After wire bonding, the devices are encapsulated in a molding compound in step 135. In that the devices have been encapsulated, the carrier holding the lead frame assemblies together is removed in step 140. An array of devices having been formed has I/O terminals exposed on the underside surface of the array. These I/O terminals may not be in a proper position for soldering onto a particular PCB sub-system. Consequently, in step 145 a non-conductive, non-solderable pattern is defined so as to provide areas for conductive paths to define the solder footprint. Having defined these conductive paths, a conductive solderable material may be applied thereon. The conductive material may be of one or more layers of metal. Some solderable conductive surfaces may include, but not necessarily limited to, NiAu, Ni, Cu, Au, NiPdAu, AuSn, NiSn, CuSn, Ag, AgSn or combinations thereof. In an example LLGA, the lead frame may be made of a nickel-plated metal sandwiched between a pre-plated topside surface and a pre-plated opposite under-side surface.

In step 150, the devices are marked with appropriate indicia. Marking may be done with precision printing or through laser marking. Singulated devices are obtained through sawing or other suitable process in step 155. The devices are packaged and shipped to the end user.

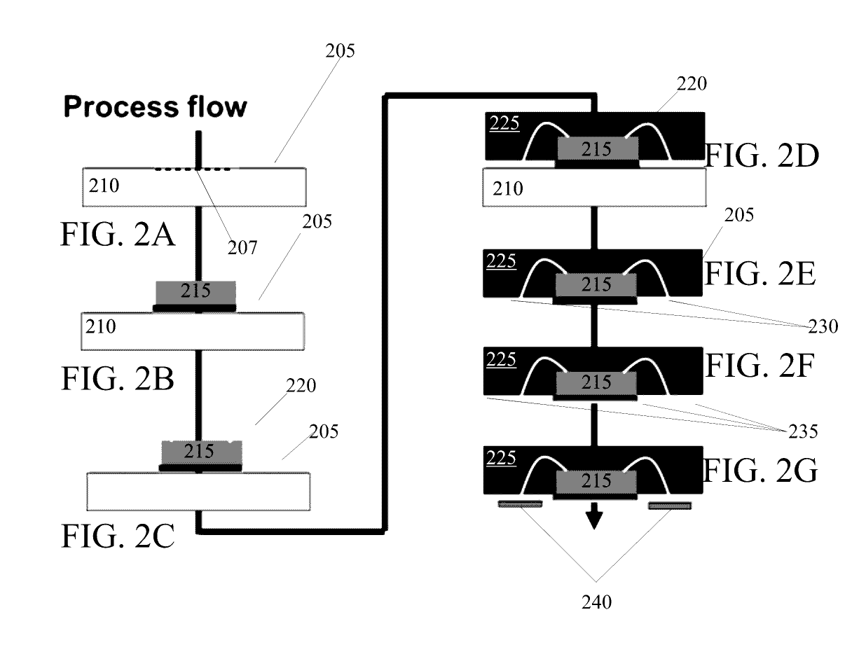

Refer to FIGS. 2A-2C. A lead frame assembly 205, according to the present disclosure, is on its temporary carrier 210. The lead frame 205, which is very thin, is plated onto the carrier. In one example embodiment, the lead frame is built-up by plating multiple layers onto a temporary carrier. Alone, this plated lead frame assembly 205 is too thin and delicate to directly handle, hence the need for a temporary carrier 210. When the assembly is complete and the lead frame 205 is anchored into a molding compound 225 and the construction is of sufficient strength, the temporary carrier 210 is removed. This temporary carrier is removed by etching as in the case of an LLGA package; the temporary carrier may be made of metal such as copper. A die attach area 207 accommodates a device die 215 attached thereon. Wire bonds 220 connect the device die's I/O terminals to corresponding I/O pads on the lead frame assembly 205. Refer to FIGS. 2D-2G. The molding compound 225 encapsulates the device 215, the wire bonds 225, and the lead frame assembly 205. The temporary carrier is removed 210 and the underside surfaces of the device die 215 and underside surfaces 235 of I/O terminals of the lead frame assembly 205.

To define a new placement for the assembled IC device I/O terminals, a non-conductive, non-solderable pattern is defined on the underside surfaces 235 of the I/O terminals. In example embodiments, techniques such as lamination, stencil printing, jet printing, or photolytic application may be used. Areas in which electrical connection is desired are not covered.

In a lamination process, a dry film of solder resist is applied by lamination on a molded lead frame on the solder side (i.e., the side on which the assembled device is attached to a system circuit board). With photolithography, the resist is developed to expose the lead frame contacts. A solderable surface is applied to these exposed contacts.

With stencil printing, a stencil solder mask is applied to the solder side of the lead frame. Areas in which a solderable surface is desired, are covered by features of the stencil. Exposed areas undergo a wet printing of solder resist.

With jet printing, a printing apparatus applies a liquid resist in areas to be covered with a solder resist. Those areas, in which a solderable surface is desired, receive no liquid resist. In this case and in the previous cases, in which a resist is used, the resist must be cured to achieve its final strength.

Thus, customized I/O terminals 240 are formed. These terminals may be formed through electro-plating, sputtering, etc. Metals used for these customized I/O terminals 240 may be aluminum, gold, silver, tin, copper, etc. or alloys thereof.

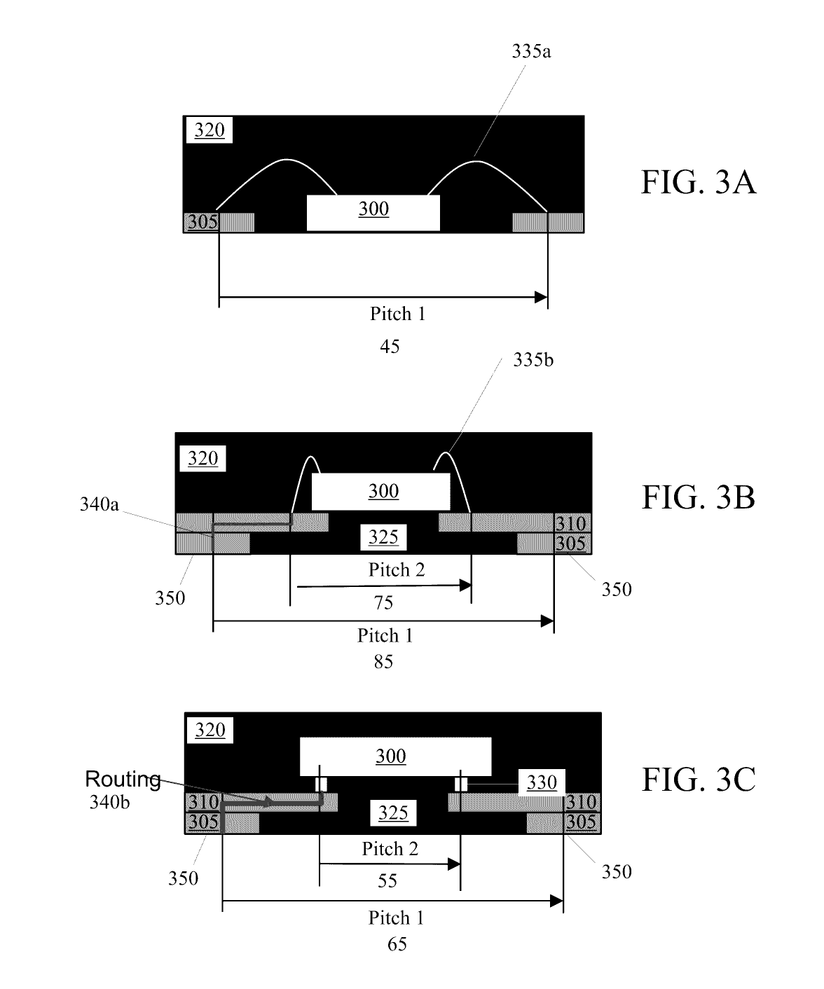

Refer to FIG. 3A. In an example embodiment, a device die 300 has been assembled onto a lead frame 305 and has wire bonds 335a to connect the device to terminals on the package (as shown in the electrical routing 340a). The device has been encapsulated in a molding compound 320. The pitch 45 between the lead frame contacts is a first distance. Further, the length of the wire bonds 335a are of a first length.

Refer to FIG. 3B. In an example embodiment according to the present disclosure, the lead frame contacts 305 having the first pitch 45, have an additional lead frame portions 310 attached to the lead frame contacts 305. Underside surfaces 350 provide electrical contact to the integrated circuit die 300 packaged therein, as the IC device is mounted in a user's application board. The additional lead frame portions 310, have a substantially reduced pitch 75. The device die 300 is encapsulated on the top side surface with a molding compound 320 and on its underside surface with additional molding compound 325. The length of bond wires 335b is substantially less than that of bond wires 335a.

Refer to FIG. 3C. In an example embodiment according to the present disclosure, the device die 300 is in a flip-chip arrangement and has bumps 330 attached to the lead frame portions 310 which are attached to the lead frame 305 (and provide the electrical routing 340b). The second pitch 55 is substantially less that the first pitch 65. As with FIG. 3B, underside surfaces 350 provide electrical contact to the integrated circuit die 300 packaged therein.

The continuing miniaturization of portable electronics necessitates thinner vertical profiles of packaged semiconductor components. Some current technology is about 0.4 mm in overall height. The technology is trending to about 0.33 mm. Even thinner packages are becoming significant thus, 0.3 mm, 0.25 mm, or even 0.15 mm are envisaged.

The number of fabricated devices can range from several hundred to even several thousand pieces. QFN package sizes may range from millimeters on a side down to about 0.5 mm×1 mm. Other leadless (metal-based) packages may include, but are not necessarily limited to, aQFN (advanced quad flat no lead), LLGA (leadless land grid array), TLA (thermal leadless array), EFLGA (electroforming type land grid array), and TLEM (transcription lead of electroforming method), etc. The embodiments in the present disclosure may also be implemented in exposed-pad leaded devices such as HSOP (heat slug outline package), HQFP (heatsink quad flat pack) or other similar package types.

The embodiments described in the present disclosure enable the reduction in material costs, such as bond wire, etc. A device with a small pitch (i.e., bump-to-bump) distance may be assembled in a package having a larger pitch, with pitch translation.

Various exemplary embodiments are described in reference to specific illustrative examples. The illustrative examples are selected to assist a person of ordinary skill in the art to form a clear understanding of, and to practice the various embodiments. However, the scope of systems, structures and devices that may be constructed to have one or more of the embodiments, and the scope of methods that may be implemented according to one or more of the embodiments, are in no way confined to the specific illustrative examples that have been presented. On the contrary, as will be readily recognized by persons of ordinary skill in the relevant arts based on this description, many other configurations, arrangements, and methods according to the various embodiments may be implemented.

To the extent positional designations such as top, bottom, upper, lower have been used in describing this disclosure, it will be appreciated that those designations are given with reference to the corresponding drawings, and that if the orientation of the device changes during manufacturing or operation, other positional relationships may apply instead. As described above, those positional relationships are described for clarity, not limitation.

The present disclosure has been described with respect to particular embodiments and with reference to certain drawings, but the invention is not limited thereto, but rather, is set forth only by the claims. The drawings described are only schematic and are non-limiting. In the drawings, for illustrative purposes, the size of various elements may be exaggerated and not drawn to a particular scale. It is intended that this disclosure encompasses inconsequential variations in the relevant tolerances and properties of components and modes of operation thereof. Imperfect practice of the invention is intended to be covered.

Where the term “comprising” is used in the present description and claims, it does not exclude other elements or steps. Where an indefinite or definite article is used when referring to a singular noun, e.g. “a” “an” or “the”, this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Numerous other embodiments of the disclosure will be apparent to persons skilled in the art without departing from the spirit and scope of the disclosure as defined in the appended claims.

1. A method for preparing an integrated circuit (IC) device, the method comprising:
providing a lead frame, the lead frame having I/O terminals surrounding a die attach region, the lead frame defined onto a temporary carrier;
attaching a device die onto the die attach region;
wire bonding the device die to the I/O terminals, the I/O terminals located in a first position;
encapsulating the device die and lead frame in a molding compound;
removing the temporary carrier from lead frame, exposing underside surfaces of the device die and I/O terminals; and
applying a non-conductive layer to the exposed underside surfaces of the device die and I/O terminals, thereby defining features in which conductive traces may be defined from the I/O terminals in the first position to customized I/O terminals located in a second position.

2. The method as recited in claim 1, wherein the lead frame I/O terminals are of a first pitch distance, and additional lead frame portions are defined on the lead frame I/O terminals to translate the pitch into a smaller second pitch distance.

3. The method as recited in claim 2,
wherein defining the lead frame onto a temporary carrier is performed by at least one of the following:
plating the lead frame assembly onto the temporary carrier; and
mounting the lead frame assembly, already pre-assembled, onto the temporary carrier;
wherein defining the additional lead frame portions onto the lead frame I/O terminals is performed by at least one of the following:
plating the additional lead frame portions onto the lead frame I/O terminals; and
mounting the additional lead frame portions, already pre-assembled onto the lead frame I/O terminals.

4. The method as recited in claim 3, wherein the smaller second pitch distance is substantially the same as a pitch distance of attachment areas on a surface of the device die.

5. The method for preparing an IC device as recited in claim 3, wherein the lead frame is selected from one of the following: LLGA, TLEM, aQFN, EFLGA, TLEM.

6. A semiconductor device, in a package, the semiconductor device comprising:
a lead frame having I/O terminals surrounding a die attach area, the I/O terminals having a first pitch between I/O terminals opposite one another;
a device die, placed in the die attach area, the device die having active device circuits, the active device circuits surrounded by I/O pads, the I/O pads having a second pitch between I/O pads opposite one another;
a lead frame portion having I/O positions corresponding to the lead frame I/O terminals, the lead frame portion I/O positions having a third pitch between I/O positions opposite one another, the third pitch substantially the same as the second pitch, the lead frame portion I/O positions in electrical contact with the lead frame I/O terminals, thereby routing electrical signals from the device die I/O pads to external electrical contacts of the package;
whereby the I/O pads of the device die are in electrical contact with corresponding lead frame portion I/O positions; and
wherein the lead frame, lead frame portions, and device die are enveloped in a molding compound, leaving surfaces of the external electrical contacts exposed.

7. The semiconductor device as recited in claim 6, wherein the lead frame or lead frame portions are at least one of the following:
plated lead frame/lead frame portions; and
pre-assembled lead frame/lead frame portions.

7. The semiconductor device as recited in claim 6, wherein the electrical contact between the I/O pads of the device and corresponding lead frame portion I/O position is achieved by at least one of the following:
the device die in a flip-chip orientation, and I/O pads make the electrical contact via solder bumps, balls, or studs; and
the device die is in normal orientation, with portions of underside in contact with the die attach area, and I/O pads make the electrical contact via wire bonds.

8. The semiconductor device as recited in claim 7, wherein the wherein the lead frame/lead frame portion is selected from one of the following: LLGA, TLEM, aQFN, EFLGA, TLEM.

9. The semiconductor device as recited in claim 8, wherein the vertical profile of the semiconductor device is less than about 0.25 mm.

10. The method as recited in claim 1, wherein the device die has been separated from a wafer that has been thinned using back grinding.

11. The method as recited in claim 10, wherein a thickness of the device die is in a range between about 30 μm to about 240 μm.

12. The method as recited in claim 1, further comprising forming solder balls on the I/O terminals.
